(19) United States
(12) Patent Application Publication
(10) Pub. No.: US 2022/0289588 A1
(43) Pub. Date: Sep. 15, 2022

(54) Ferroelectric, And Suitable Method And Use Therefor

(71) Applicant: Quantum Power Munich GmbH, Gruenwald (DE)

(72) Inventor: Marcus Reid, Muenchen (DE)

(21) Appl. No.: 17/638,771

(22) PCT Filed: Sep. 3, 2020
(86) PCT No.: PCT/EP2020/074552

§ 371 Date: Feb. 25, 2022

(30) Foreign Application Priority Data
Sep. 3, 2019 (DE) 10 2019 213 367.3
Oct. 31, 2019 (DE) 10 2019 216 890.6

(51) Int. Cl. C01G 25/00; H01L 41/187; H01L 41/43; H01L 39/12

(52) U.S. Cl. CPC C01G 25/006; H01L 41/1871; H01L 41/1876; H01L 41/43; H01L 39/125; C01P 2002/54; C01P 2006/40; C01P 2002/72

(57) ABSTRACT

The invention relates to a ferroelectric, which has a piezoelectric material having a hafnium proportion of 2% or less, to the use of a ferroelectric of this type in energy generation and for implementation in memory, processor and sensor technologies, to the use of a ferroelectric, in which use energy demand is lowered by superconductivity, and to a method for producing a ferroelectric, in which method a sintering method is used.

The present invention relates to a ferroelectric or ferroelectric material and also to suitable methods and uses therefor.

Conventional ferroelectrics, more particularly piezoelectric materials with perovskite structure, which contain zirconium and titanium in the interior of the molecular structure (B-side), such as materials based on PZT and BZT, for example, are the most common piezoelectric materials on the market.

PZT (lead zirconate titanate), for example, is produced using zirconium oxide. Zirconium oxide which is mined, hence with the status of a naturally occurring mineral, has a hafnium fraction of primarily 2-3%, with up to 5% also being possible. PZT materials, accordingly, are typically produced with a zirconium oxide which contains 2-2.5% hafnium.

It is already known from U.S. Pat. No. 7,059,709, furthermore, that a reduction in hafnium relative to the naturally occurring level has a positive influence on certain piezoelectric properties, particularly in the context of a thin-film application, as in the case of inkjet printers, for example. A disadvantage in the prior art, however, is that the results have to date been achievable only in the context of particular applications, as in the case of inkjet printers, for example.

The objects of the present invention are to overcome the disadvantages of the prior art. A further aim is to improve the piezoelectric properties of the ferroelectrics not only for thin-film technologies. Another aim is to increase the fraction of the rhombohedral structure in the ferroelectrics.

These objects are achieved with the subject matter of claims 1, 9, 10, 11 and 12.

In the invention it has emerged that ferroelectrics, e.g., PZT, and materials which are produced with a zirconium oxide containing less than 2% hafnium have significantly better piezoelectric properties. The zirconium oxide used ought preferably to be as pure as possible, in other words to contain ideally no hafnium. If a zirconium oxide having a relevant hafnium fraction of more than 2%, for example, is used, the hafnium has the property of supporting the tetragonal phase and at the same time suppressing the rhombohedral phase. If, conversely, a relevant hafnium fraction of below 2%, for example, preferably or such as below 1%, is used, then the hafnium has the property of suppressing the rhombohedral phase to less of an extent.

In light of the reduction in the hafnium fraction of less than 2%, which does not occur naturally, the ferroelectric of the present application may be used either in energy production or for implementation in memory, processor and sensor technologies and actuators. It has also emerged that there is a lowering of the energy requirement in the presence of and as a result of the superconductivity.

Further developments of the features of the invention are a subject of the dependent claims.

In accordance with the present application, for a hafnium fraction reduced relative to the naturally occurring level, a dielectric loss factor of 0.2% or less is advantageously attained. It is obtained more particularly for a given dielectric constant and/or piezoelectric effect d33. The ferroelectrics of the present application, therefore, can lead to a considerable energy saving in the context of the use of electrical components or circuits.

Advantageously, furthermore, a two-phase or multiphase material is used as ferroelectric, and so, for a reduced hafnium fraction, the rhombohedral phase is increased or suppressed to less of an extent. As a result of the increase in the rhombohedral phase, the piezoelectric properties are increased.

As a further advantage it has been found that for a reduced hafnium fraction of less than or equal to 2%, for a given electrical loss, i.e., between comparable ferroelectrics with and without reduced hafnium fraction, an at least 50% or more increase is obtained in the relative dielectric constant and/or in the piezoelectric effect d33. Furthermore, for virtually the same relative dielectric constants, an at least 50% reduction is attained in the electrical loss. It has emerged advantageously, moreover, that for a given piezoelectric effect d33, an at least 50% reduction in the electrical loss is attained. These effects likewise contribute to an improved energy balance when they are respectively deployed. In view of the improved energy balance, it is possible to increase the packing density of the components, thereby also obtaining higher clocking levels or clock frequencies relative to conventional components.

Because of the inventive finding of the increase in the rhombohedral phase through the reduction in the hafnium fraction, it is possible advantageously for materials to be able to be produced, in particular, not only in thin-film technology but instead in material thicknesses of between 5 nanometers up to approximately 4 cm.

Particular materials which may be used are, advantageously, piezoelectric materials based on PZT (lead zirconate titanate), PLZT (lead lanthanum zirconate titanate), PSZT (lead strontium zirconate titanate), PLSZT (lead lanthanum strontium zirconate titanate), BZT (barium zirconate titanate) and/or BSZT (barium strontium zirconate titanate), for which the rhombohedral structure can be increased by reduction in the hafnium fraction, thereby improving the piezoelectric properties. If, therefore, a PZT material is produced which is established in the direction of a rhombohedral phase, thus containing a zirconium/titanium ratio of Zr52%/Ti48% or more zirconium, then the effect becomes ever more distinctly noticeable.

For example it is possible in the case of PZT with a quasi-hafnium-free zirconium oxide (high-purity zirconium oxide, reactor grade), which contains a Zr/Ti ratio of around Zr53%/Ti47%, or more zirconium, to attain a phase-critical range in which the rhombohedral phase and the tetragonal phase are present simultaneously. A material of this kind has outstanding properties in almost every respect (dielectric constant, piezoelectric deformation and loss factor), which may be substantially better than comparable PZT materials.

Further advantageous developments are subjects of the further dependent claims and further embodiments herein.

In summary therefore, an improvement in the piezoelectric properties of the above-stated piezoelectric materials of 100% or more is achieved for materials produced with a zirconium oxide containing less than 2 or 1.5% hafnium, relative to identical materials produced with a zirconium oxide containing 2% or more hafnium. With preference high-purity zirconium oxide is used, and specifically as little hafnium as possible. It has generally emerged that hafnium-reduced or hafnium-free piezoelectric material, based for example on PZT or BZT, combines the best properties of hard PZTs with the good properties of soft PTTs and can therefore be put to outstanding use in energy conversion applications.

Examples below show the respective piezoelectric properties between commercial customary piezoelectric materials as ferroelectrics in one case with naturally present hafnium fraction and with reduced hafnium fraction for comparison, i.e examples below show a comparison of the piezoelectric properties of commercial customary piezoelectric materials as ferroelectrics, in one case with a naturally present hafnium fraction, and in another case with a reduced hafnium fraction

Basically, the rule is that the lower the dielectric losses, the lower also the other values of the piezoelectric properties, such as the relative dielectric constant and the piezoelectric effect.

According to Example 1 it can be seen that the material of the present application with a reduced hafnium fraction, presently less than 0.01%, relative to the best comparable conventional material with natural hafnium fraction, presently of 0.6%, from the industry, has significantly higher values for the relative dielectric constant and for the piezoelectric effect.

### EXAMPLE 1: IMPROVEMENT IN THE DIELECTRIC CONSTANT AND IN THE PIEZOELECTRIC EFFECT

| | Del-Piezo | QPM PZT #1 |
|---|---|---|
| | DL-40 with | Hafnium |
| Material | hafnium 0.6% | fraction <0.01% |
| relative dielectric constant ε | 350 | 1574 |
| dielectric losses tan δ | 0.3% | 0.2% |
| piezoelectric effect d33 | 145 | 361 |

### EXAMPLE 2: IMPROVEMENT IN THE DIELECTRIC LOSSES

| | Del-Piezo | QPM PZT #1 |
|---|---|---|
| | DL-45HD with | Hafnium |
| Material | hafnium 0.6% | fraction <0.01% |
| relative dielectric constant ε | 1550 | 1574 |
| dielectric losses tan δ | 0.5% | 0.2% |
| piezoelectric effect d33 | 360 | 361 |

### EXAMPLE 3: IMPROVEMENT IN THE DIELECTRIC LOSSES

| | Standard APC | QPM PZT #1 |
|---|---|---|
| | Material 841 with | Hafnium |
| Material | hafnium 0.6% | fraction <0.01% |
| relative dielectric constant ε | 1375 | 1374 |
| dielectric losses tan δ | 0.4% | 0.2% |
| piezoelectric effect d33 | 300 | 315 |

Examples 2 and 3 show that the material of the present application with reduced hafnium fraction, presently less than 0.01%, with comparable values of the piezoelectric properties such as relative dielectric constant and of the piezoelectric effect d33, produces significantly lower dielectric loss. In this case the dielectric loss reduces by at least 50% or more, for example.

### EXAMPLE 4: FURTHER-IMPROVED DIELECTRIC LOSSES

| | QPM PZT #2 |
|---|---|
| | Hafnium |
| Material | fraction <0.01% |
| relative dielectric constant ε | 1347 |
| dielectric losses tan δ | 0.1% |
| piezoelectric effect d33 | 300 |

Example 4 illustrates that a dielectric loss of 0.1% is also achievable according to material composition, this being the case with virtually the same piezoelectric properties such as relative dielectric constant and the piezoelectric effect, and shows a further halving of the losses for only slightly lower values for the relative dielectric constant and the piezoelectric effect.

In addition to the reduction in the loss factor, the ferroelectric can also be converted to the state of superconduction, through reduction in or even removal of hafnium, in order to achieve a further significant lowering of the energy losses in corresponding applications, as in the case of electrical components or circuits, for example. It is common knowledge that the superconductivity of a material is related to the formation of or presence of a rhombohedral phase. This relationship was recognized in research into the interface between lanthanum aluminate and strontium titanate. Accordingly, this material, consisting of lanthanum aluminate and strontium titanate, undergoes transition to a rhombohedral phase at below 30 kelvins, causing its electrical resistance to drop steadily as the temperature falls. The superconductivity occurs at below 200 millikelvins.

In accordance with the present application, therefore, the reduction in or the removal of hafnium promotes the development of a rhombohedral phase at room temperature, thereby enabling high-temperature superconduction.

A corresponding superconductivity is evident, for example, in a compound QPM PZT with the elements lead Pb, strontium Sr, zirconium Zr, titanium Ti, iron Fe, lanthanum La, aluminum Al and nickel Ni, having a hafnium fraction of below 0.01%.

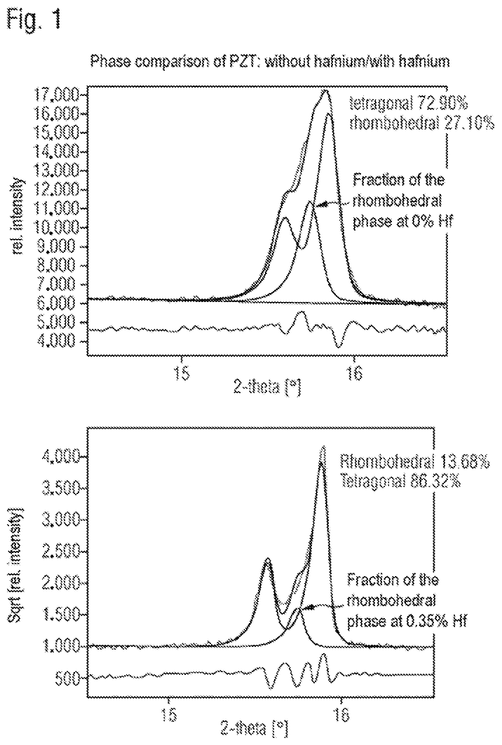

FIG. 1 indicates the extent to which the rhombohedral structure or phase has been significantly increased as a result of a reduction in the hafnium fraction. The measurement took place on the basis of common diffractometer measuring methods, as described for example in the book “Rietveld Refinement, Practical Diffraction Pattern Analysis using TITOPAS” by Dinnebier, Leineweber, Evans, 2018, and was carried out in the Debye-Scherrer geometry, with the intensity being determined relative to the diffraction angle theta. The respective phases are determined in folded form from the total intensity signal measured.

The ferroelectrics of the present application can be used fundamentally in acceleration sensors, rotation-rate, pressure and force sensors, and ultrasonic sensors, microbalances and knock sensors in motor vehicle engines, and also actuators or micromechanical actuator elements, examples being piezoelectric motors (squigglers), ultrasonic motors, for lens autofocusing or watch drives, for example; in the area of micropositioning and nanopositioning systems, the scanning tunneling microscope, the scanning electron microscope and the atomic force microscope are piezoelectrically driven systems. In valve technology, noteworthy components include automobile injection nozzles (production start 2000 for diesel engines), proportional pressure regulators and printheads of inkjet printers. Pickups, electroacoustic delay lines as in older PAL or SECANT color televisions, batteryless radio equipment (switches) and optical modulators are likewise piezoelectric components. Supply equipment uses many of the stated components. The piezoelectric crystal is utilized, moreover, for the purpose of generating cold atmospheric-pressure plasma, which is employed in particular for surface activation, microbial reduction and odor abatement in medicine.

1. A ferroelectric which comprises a piezoelectric material having a hafnium fraction of 2% or less.

2. The ferroelectric as claimed in claim 1, where a dielectric loss factor for the ferroelectric is 0.2% or less for a dielectric constant ε of more than 1000 and a piezoelectric effect d33 of more than 300.

3. The ferroelectric as claimed in claim 1, comprising a two-phase or multiphase material.

4. The ferroelectric as claimed in claim 1, wherein for a given electrical loss, the ferroelectric attains an at least 50% increase in a relative dielectric constant and/or in a piezoelectric effect d33.

5. The ferroelectric as claimed in claim 1, wherein for a given relative dielectric constant, the ferroelectric attains an at least 50% reduction in an electrical loss.

6. The ferroelectric as claimed in claim 1, wherein for a given piezoelectric effect d33 attains an at least 50% reduction in an electrical loss.

7. The ferroelectric as claimed in claim 1, wherein the ferroelectric has a thickness of at least 5 nanometers up to 4 cm.

8. The ferroelectric as claimed in claim 1, wherein the piezoelectric material is a PZT or a BZT.

9. (canceled)

10. A device comprising the ferroelectric as claimed in claim 1, wherein the device is a memory device, as processor, or a sensor.

11. (canceled)

12. A method for producing the ferroelectric as claimed in claim 1, wherein a sintering method is used.

13. The method as claimed in claim 12, where producing takes place using a ZrO₂ powder.

14. (canceled)

15. A superconductor comprising the ferroelectric of claim 1.

16. An actuator comprising the ferroelectric of claim 1.
